(19) United States
(12) Patent Application Publication
(10) Pub. No.: US 2003/0193979 A1
(43) Pub. Date: Oct. 16, 2003

(54) Semiconductor laser device including multiple-quantum wells of different widths that uses carrier redistribution to adjust wavelength of light

(76) Inventor: Ching-Fuh Lin, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/216,711

(22) Filed: Aug. 13, 2002

(30) Foreign Application Priority Data
Apr. 12, 2002 (TW) 091107443

(51) Int. Cl. H01S 5/00

(52) U.S. Cl. 372/45

(57) ABSTRACT

There is provided a semiconductor laser device including multiple-quantum wells of different widths that uses carrier redistribution to adjust the wavelength if light. The semiconductor laser device according to the present invention is fabricated by forming at least two groups of multiple-quantum wells on a semiconductor substrate, so that the carrier distribution within the multiple-quantum wells can be readjusted according to the variation of external environment, and thus the wavelength of light can be adjusted as well.

### FIELD OF THE INVENTION

The present invention is generally related to a semiconductor laser device, and more particularly to a semiconductor laser device including multiple-quantum wells of different widths that uses carrier redistribution to adjust wavelength.

### BACKGROUND OF THE INVENTION

The application of semiconductor laser device should be based on the adjustment of its characteristics, for example, light intensity, wavelength and so on. However, the wavelength conversion technique for semiconductor laser device is a desired characteristic that is a basic element of the practical application involved with optical communication or optical switch.

For the current state of art, the most widely used wavelength conversion techniques for semiconductor laser device falls into two categories: Free-carrier plasma effect and thermal tuning. The manner of wavelength conversion according to the two conventional techniques as stated above is either established on the basis of adjustment of refractive index of the ingredient of semiconductor laser device through carrier injection or temperature variation, and further the wavelength of laser light is adjusted; or established on basis of the use of quantum confined stark effect of the quantum well to control the transition energy of quantum well and thus the transition-state wavelength (wavelength of laser light) is adjusted; or established on basis of the use of non-linear crystal having a stronger electro-optical effect to convert the wavelength of incident laser light in cooperation with a high-level electric field reaction.

The three manners of wavelength conversion for semiconductor laser device mentioned in the introduction are capable of adjusting the wavelength of laser light within the extent of 10 nm due to the confinement of the refractive index of the ingredient of semiconductor laser device or the energy of quantum well. On the other hand, the power loss of the nonlinear-crystal based semiconductor laser device is hard to be controlled. Moreover, the fabrication process of semiconductor laser device is very inextricable, which cause a reduction in yield. And again, the variables for use in optimal control have to be increased, which indicates that its applicability in photo switch is decreased.

Therefore, the present invention is focused on the presentation of a solution to deal with above-mentioned disturbance incurred in the prior multiple-quantum well laser device. The present invention basically adjusts the wavelength of laser light emitted from multiple-quantum well laser device by readjusting the carrier distribution in the multiple-quantum well according to the variation of external environment, so the multiple-quantum well laser device formed thereby is more adapted for use with optical communication device, optical switch and optical integrated circuit device.

### SUMMARY OF THE INVENTION

A major object of the present invention is to provide a semiconductor laser device including multiple-quantum wells of different widths which uses carrier redistribution to adjust wavelength of laser light, which is appropriate in a wide range of adjustment and provided with a better applicability.

Another object of the present invention is to provide a semiconductor laser device including multiple-quantum wells of different widths being made by a fabrication process that is simpler than other adjustment techniques. In this invention, only a ridge-waveguide Fabry-Perot high-power laser is needed to be produced.

It is a further object of the present invention to provide a semiconductor laser device including multiple-quantum wells of different widths, wherein the wavelength adjustment of laser light is achieved through temperature variation only without other additives. However, the wavelength adjustment of laser light also can be achieved through voltage regulation only.

It is a further object of the present invention to provide a semiconductor laser device including multiple-quantum wells of different widths, which makes use of the characteristics that the wavelengths of laser lights will compete against one another to drive the extinct ratio of laser to be very large, such that the signal modulation can be accomplished more easily.

The present invention is attained by a semiconductor laser device including multiple-quantum wells of different widths formed on a semiconductor substrate, wherein the carrier distribution within the multiple-quantum wells can be readjusted according to the variation of external environment, and further the wavelength of laser light for each multiple-quantum wells can be resolved.

The foregoing and features and advantages of the present invention will become more apparent through the following descriptions with reference to the accompanying drawings, in which:

### BRIEF DESCRIPTION OF THE DRAWINGS

FIG. 1 shows an example of epitaxial structure of the multiple-quantum wells according to the present invention;

FIG. 2 shows a characteristic plot explicating the relationship between the carrier concentrations within the two multiple-quantum wells and temperature variation according to the present invention;

FIG. 3 shows a characteristic plot explicating the relationship between the threshold current of a ridge-waveguide laser device having a length of 500 μm and temperature variation according to the present invention;

FIG. 4 shows a characteristic plot explicating the relationship between the external quantum efficiency and temperature variation according to the present invention;

FIG. 5 shows a characteristic plot explicating the relationship between the laser wavelength and temperature variation according to the present invention; and

FIG. 6 shows the ratio of the light power of the semiconductor laser device at a wavelength of 1417 nm and a wavelength of 1370 nm under temperature variation to the total radiant power according to the present invention.

### DETAILED DESCRIPTION OF THE PREFERRED EMBODIMENT

The present invention is accomplished on the basis of the utilization of the non-uniformity of carrier distribution in multiple-quantum well to form multiple quantum wells with different width. Further, due to the characteristics that the mean free path of carrier under different temperatures is different from one another, the present invention involves with the considerations to carrier distribution and the variation in gain of semiconductor laser device ingredients, and the equilibrium relationship between the gain and loss of the semiconductor laser device ingredients. The present invention finally addresses a semiconductor laser device including multiple-quantum wells with different widths that uses carrier redistribution to adjust wavelength of light, and whose principle and function will be defined afterwards.

The semiconductor laser device including multiple-quantum wells with different widths that uses carrier redistribution to adjust wavelength of laser light according to the present invention includes a semiconductor substrate formed from a material selected from group III-V elements, and multiple-quantum wells which at least include a combination of two groups of multiple-quantum well to be fabricated on the semiconductor substrate, wherein the number of quantum wells that has a shorter wavelength of laser light is more than the number of quantum wells that has a longer wavelength of laser light. The carrier distribution within the multiple quantum wells can be readjusted according to the variation of external environment, so as to resolve whether the dominant carrier in the 2-D carrier distribution is electron or hole, and further determines the wavelength of laser light emitted from the multiple-quantum wells of the semiconductor laser device.

The dominant carrier is resolved by the length and composition of separate confinement heretostructure (SCH) and the width and ingredient of the quantum well. With the technique of formation of multiple-quantum well, the present invention first sets the length of the separate confinement heretostructure and then determines whether the carrier concentration is higher near either P-side or N-side while carrier injection is taking place, and thereby resolves dominant carrier. Because the dominant carrier has been predetermined, the wavelength of laser light can be calculated. In addition, the switching of the wavelength of laser light from the semiconductor laser device can be achieved by designing the quantum wells as to be of different widths or different quantum well bases and barriers, which results in a different transition wavelength corresponding to a ground-state energy level.

For a semiconductor laser device, if it is desired to meet the necessary laser condition, the cavity net gain must be equal to zero, which brings out the necessary laser condition to be expressed in the following deductive formula: g_{c}=0→g_{eff}−α₁−αₘ=0,g_{eff}=Γgₐ, where g_{c} is the cavity net gain being equal to the equivalent gain g_{eff} minus mirror loss αᵢ and internal loss αₘ, and where the equivalent gain g_{eff} is equal to the confinement factor times the gain of the ingredient of the active area under a specific carrier concentration. For a general ingredient of semiconductor laser device, if a specific structure, for example, optical Grating, is not used, the relationship between the loss and the wavelength will not be as sensitive as that between the gain and the wavelength. This means that if it is intended to allow the laser light of different wavelength to achieve the necessary laser condition in a simple laser optical cavity according to the present invention, the gain spectrum of the ingredients in the active area has to be adjustable, so as to adjust the wavelength of the peak gain.

While using the multiple quantum well laser, the present invention first fabricates multiple-quantum wells formed from different ingredients on the same semiconductor substrate. Quantum wells of different wavelengths of laser light can be designed according to the evaluation based on quantum mechanics. The gain spectrum for the multiple-quantum wells under different carrier concentrations can be calculated by virtue of Luttinger-Kohn approach, and the gain spectra corresponding to multiple-quantum wells of different widths can be overlappingly incorporated to determine the wavelength of the peak gain. Since multiple-quantum wells of different widths correspond to different transition energies, it is possible to generate a considerable drift of the wavelength with the difference of the carrier concentration of each quantum wells.

Heretofore, the spirit of the present invention has been described in more detail. An exemplificative embodiment will be given as follows in order to verify the above-described principles, and those of skill in the art will realize sufficient knowledge to implement the present invention in reference to the descriptions of the following exemplificative embodiment.

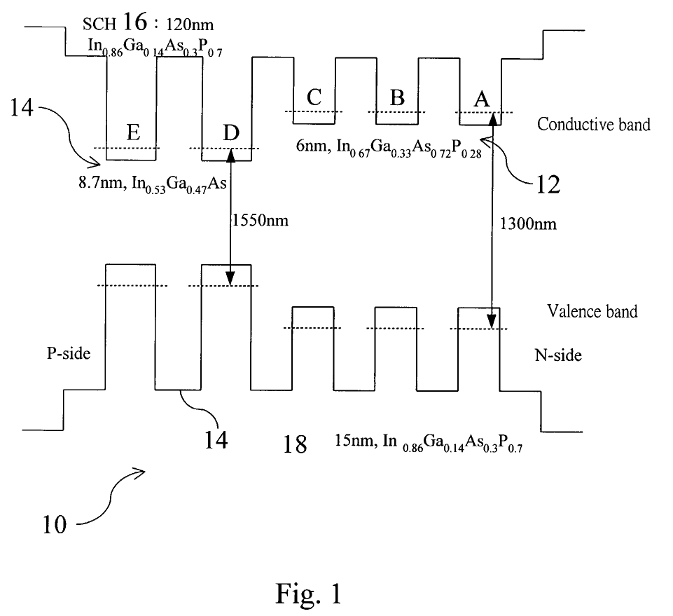

According to the present invention, a multiple-quantum well structure 10 being fabricated in compliance with the above-mentioned principle is explicated in FIG. 1. As shown, the multiple-quantum well structure 10 of different width includes two groups of multiple-quantum wells of different widths, the first one is the multiple-quantum well 12 including three quantum wells A, B and C each has a width of 6 nm, and its ingredient is In_{0.67}Ga_{0.33}As_{0.72}P_{0.28} and the wavelength of laser light is 1300 nanometers. The second one is the multiple-quantum well 14 including two quantum wells D and E each has a width of 8.7 nm, and its ingredient is In_{0.53}Ga_{0.47}As and the wavelength of laser light is 1550 nanometers. The length of the separate confinement heretostructure 16 is 120 nanometers. The barrier 18 for each quantum wells in the semiconductor substrate is 15 nanometers. The detailed structure and ingredient for each quantum well are illustrated in the table below:

| | | | Width |
|---|---|---|---|
| Layer | Ingredient | Doping | (/nm) |
| | P-InP | | |
| | InGaAsP quaternary @ 1.1 μm | Undoped | 75 |
| SCH 16 | In_{0.86}Ga_{0.13}As_{0.3}P_{0.7} | Undoped | 45 |
| Quantum Well E | In_{0.53}Ga_{0.47}As | Undoped | 8.7 |
| Energy Barrier | In_{0.86}Ga_{0.14}As_{0.3}P_{0.7} | Undoped | 15 |
| Quantum Well D | In_{0.53}Ga_{0.47}As | Undoped | 8.7 |
| Barrier | In_{0.86}Ga_{0.14}As_{0.3}P_{0.7} | Undoped | 15 |
| Quantum Well C | In_{0.67}Ga_{0.33}As_{0.72}P_{0.28} | Undoped | 6 |
| Barrier | In_{0.86}Ga_{0.14}As_{0.3}P_{0.7} | Undoped | 15 |
| Quantum Well B | In_{0.67}Ga_{0.33}As_{0.72}P_{0.28} | Undoped | 6 |
| Barrier | In_{0.86}Ga_{0.14}As_{0.3}P_{0.7} | Undoped | 15 |
| Quantum Well A | In_{0.67}Ga_{0.33}As_{0.72}P_{0.28} | Undoped | 6 |
| Barrier | In_{0.86}Ga_{0.14}As_{0.3}P_{0.7} | Undoped | 45 |
| | InGaAsP quaternary @ 1.1 μm | Undoped | 75 |
| Semiconductor | N-InP | 1e18 | 500 |
| Laser Device | | | |
| | N+ InP Substrate | | |

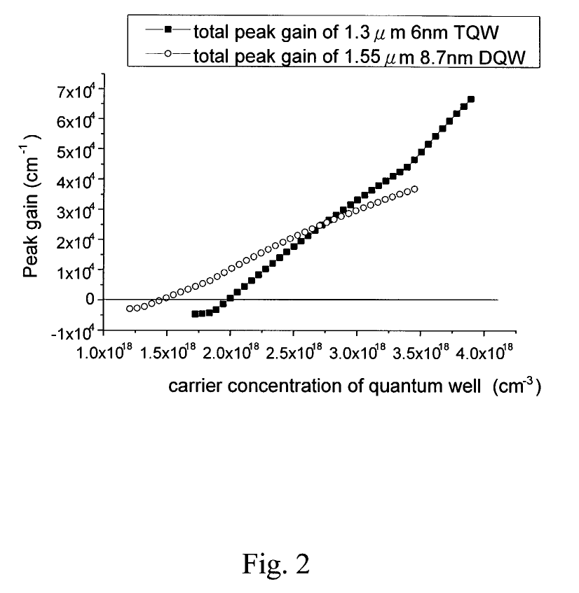

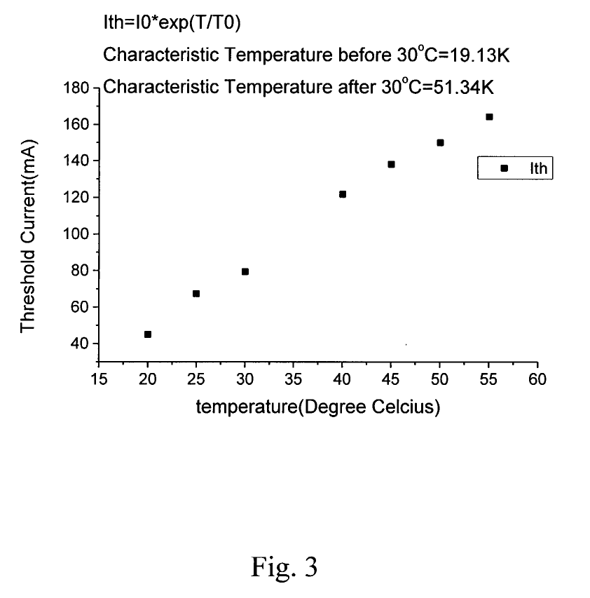

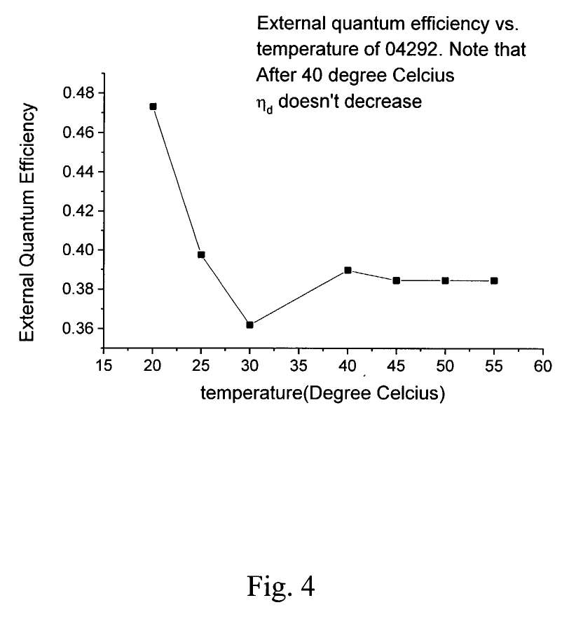

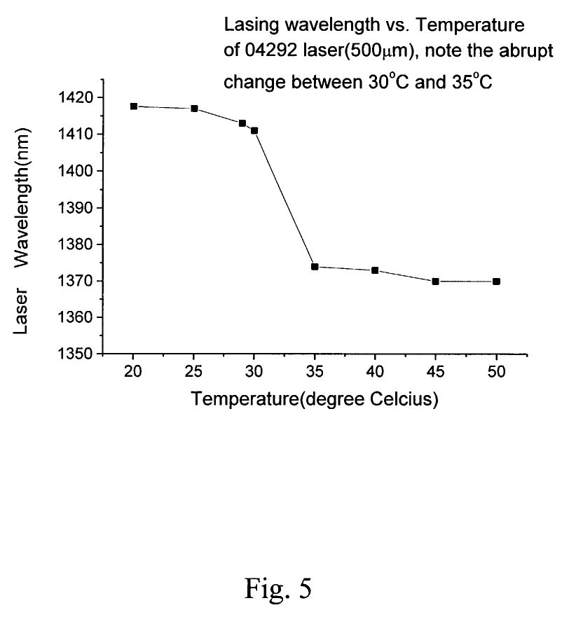

Next, the relationship between the carrier concentration within the two multiple-quantum wells of different widths and their peak gain is illustrated in the curve diagram of FIG. 2. It can be seen from FIG. 2 that both the quantum wells D and E of the second multiple-quantum well 14 have a higher peak gain under a low carrier concentration. However, the three quantum wells A, B and C of the first multiple-quantum well 12 have a higher peak gain than the two quantum wells of the second multiple-quantum well 14. This is because the first multiple-quantum well 12 has one more quantum well than the second-multiple quantum well 14. It can be understood that the dominant carrier in this example is electron, that is, the carrier concentration near N-side is higher. If the multiple-quantum well structure is formed by metal organic chemical vapor deposition (MOCVD) and thus makes a ridge-waveguide semiconductor laser device, the relationship between the threshold current and temperature variation is explicated in FIG. 3. The relationship between the external quantum efficiency and temperature variation is explicated in FIG. 4, and relationship between the laser wavelength and temperature variation is explicated in FIG. 5.

It can be known from the above discussions in conjunction with the multiple-quantum well structure with different width as shown in FIG. 1 that though the carrier distribution under room temperature approaches N-side, the quantum wells of the second multiple-quantum well has a higher gain, and the necessary laser condition is achieved at the wavelength of 1417 nm in under gain/loss balance, which is representative of the corresponding wavelength of the peak gain while high-concentration carriers are injecting into the quantum wells of the second multiple-quantum well 14. At the same time, the magnitude of carrier concentration should be indicated at the intersection of the two curves of FIG. 2. However, when the mean free path of carrier is decreased due to temperature increases, the number of carrier accumulated in the proximity of N-side of the three quantum wells of the first multiple-quantum well 12 is more, so that the gain of the first multiple-quantum well 12 is greater than that of the second multiple-quantum well 14. In this manner, this results in a rapid decrease of wavelength of laser light for the multiple-quantum well structure 10 from 1417 nm to 1370 nm while the temperature increases from 30° C. to 35° C. The laser wavelength of 1370 nm corresponds to the light emitted from the first multiple quantum well 12.

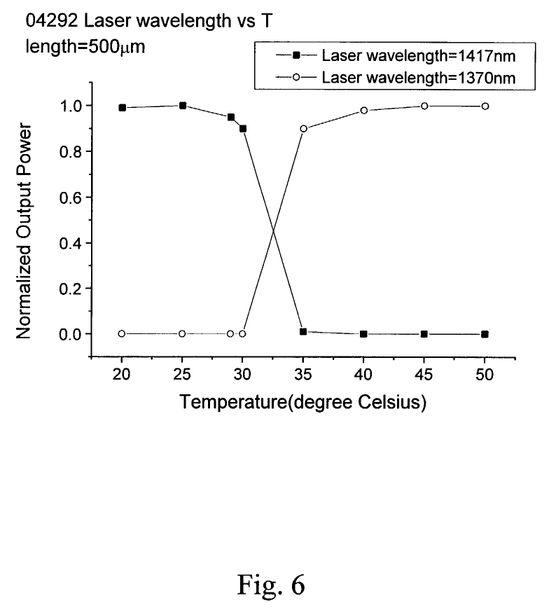

The relationship between the light intensity at a wavelength of laser light of 1417 nm and the light intensity (radiant power) at a wavelength of laser light of 1374 nm in terms of temperature variation is explicated in FIG. 6. Because the necessary laser condition is achieved depending on the increase of the gain for each quantum well and the gain/loss balance, as one of the two laser wavelengths generates pulsed laser light, theoretically the extinct ratio should reside at negative infinity. The extinct ratio will be better if a greater temperature difference is taken into account. Furthermore, both the external quantum efficiency at a temperature of 25° C. and a wavelength of 1417 nm and the external quantum efficiency at a temperature of 35° C. and a wavelength of 1370 nm will be around 0.4, this means that their light-emitting efficiencies are about the same and their applicability in optical switch and applications that involves with beam-splitting by temperature variation.

The foregoing embodiment is given for the purpose of illustrating the possibility that wavelength adjustment can be accomplished by carrier redistribution. On the side, carrier redistribution not only can be accomplished by temperature variation, but can be accomplished through current injection, voltage regulation, external mechanical stress, magnetic field, illumination, etc. For example, current injection may change the carrier distribution in quantum well due to band-filling effect, voltage regulation may change the electric field in the quantum well and result in a drift of carrier, applying magnetic field or mechanical stress may cause the deformation of the profile of quantum well and illumination may change the number of carriers in individual quantum well to break its equilibrium. Once the carriers in the quantum well are redistributed, the wavelength of laser light may be changed as well, which further achieves the object of wavelength adjustment.

As a result, the semiconductor laser device including multiple-quantum wells of different widths according to the present invention is possible to adjust the wavelength of laser light through carrier redistribution, and in this way it is appropriate for a wide range of applications and provided with a better applicability. It is advantageous in the aspect that the fabrication process of semiconductor laser device according to the present invention is much simpler than that of the prior art. Moreover, the present invention also makes use of the characteristics that the wavelengths of laser lights will compete against one another to drive the extinct ratio of laser to be very large, such that the signal detection can be carried out more easily.

While the invention has been described in terms of what are presently considered to be the most practical and preferred embodiments, it is to be understood that the invention need not be limited to the disclosed embodiment. Adversely, it is intended to cover various modifications and similar arrangements included within the spirit and scope of appended claims which are to be accorded with the broadest interpretation so as to encompass all such modifications and similar structures.

What is claimed is:

1. A semiconductor laser device including multiple-quantum wells of different widths or ingredients which uses carrier redistribution to adjust a wavelength of light, comprising:
a semiconductor substrate; and
multiple-quantum wells fabricated on said semiconductor substrate, wherein a carrier distribution in said multiple-quantum wells can be readjusted according to a variation of external environment to determine a wavelength of light emitted from said multiple-quantum wells.

2. The semiconductor laser device according to claim 1 wherein said multiple-quantum wells at least include a combination of two groups of multiple-quantum well.

3. The semiconductor laser device according to claim 1 wherein a dominant carrier which controls a distribution of two-dimensional carriers within said multiple-quantum wells comprises either an electron or a hole.

4. The semiconductor laser device according to claim 1 wherein said dominant carrier is resolved by a length and composition of a separate confinement heretostructure and a width and ingredient of said multiple-quantum wells.

5. The semiconductor laser device according to claim 3 wherein said dominant carrier is resolved by a length and composition of a separate confinement heretostructure and a width and material of said multiple-quantum wells.

6. The semiconductor laser device according to claim 1 wherein a switching to said wavelength can be achieved by designing said multiple-quantum wells as to be of different widths or different quantum well ingredients and barriers, which results in a different transition wavelength corresponding to a base-state energy level.

7. The semiconductor laser device according to claim 1 wherein said substrate is formed from an ingredient selected from group III-V or II-VI elements.

8. The semiconductor laser device according to claim 1 wherein said semiconductor laser device is a ridge-waveguide laser device, or said wavelength is resolved through a distribution feedback laser device with grating or a distributed Bragg reflection laser device, and wherein a period of said grating is related to said wavelength of light and a range of adjustment to said wavelength of light.

9. The semiconductor laser device according to claim 1 wherein the number of quantum wells that has a shorter wavelength of light is more than the number of quantum wells that has a longer wavelength of light.

10. The semiconductor laser device according to claim 6 wherein the number of quantum wells that has a shorter wavelength of light is more than the number of quantum wells that has a longer wavelength of light.

11. The semiconductor laser device according to claim 1 wherein said variation of said external condition can be generated by either the variation of temperature, voltage, current, mechanical stress or illumination intensity, so as to adjust said wavelength of light.
